(19) United States
(12) Patent Application Publication
(10) Pub. No.: US 2017/0108538 A1
(43) Pub. Date: Apr. 20, 2017

(54) ISOLATED PROBE AND METHOD FOR POWER DEVICE MONITORING

(71) Applicant: General Electric Company, Schenectady, NY (US)

(72) Inventors: Nicolas Wannenmacher, Bavaria (DE); Alvaro Jorge Mari Curbelo, Bavaria (DE); Thomas Alois Zoels, Bayern (DE); Miguel Garcia Clemente, Bayern (DE)

(21) Appl. No.: 14/887,372

(22) Filed: Oct. 20, 2015

(51) Int. Cl. G01R 15/14; G01R 19/25

(52) U.S. Cl. CPC G01R 15/14; G01R 19/2513

(57) ABSTRACT

A probe device includes a measurement stage and an output connection. The measurement stage has a circuit configured to be connected with a power device under measurement, to measure one or more of a voltage or a current of the power device under measurement. The measurement stage is configured for at least one of a power supply rail or a reference of the measurement stage to be coupled to an electrode of the power device when the one or more of the voltage or the current is measured. The output connection is configured to communicate one or more of the voltage or the current of the power device under measurement that is measured or a derived parameter to a digital processing device or an external computer acquisition system.

### FIELD

Embodiments of the subject matter described herein relate to probe devices and systems that monitor power devices, such as power switches.

### BACKGROUND

Power devices can include power switches, such as insulated gate bipolar transistors (IGBTs), reverse conducting IGBTs, BIGTs, MOSFETS, Thyristors, integrated gate-commutated Thyristors (IGCTs), diodes (including power diodes), etc. These devices can be used to control the conduction of current to one or more other electronic loads or systems. To validate control algorithms of the power devices or for health monitoring purposes, many voltages and currents need to be monitored at the IGBT level with some requirements that cannot easily be met using standard measurement systems. For example, a conventional approach for these kind of measurements is to use an analog, high voltage differential probe connected to an oscilloscope. The main drawback of this setup is the measurement error induced by the common mode voltage and the susceptibility of the signal due to cabling to the oscilloscope.

### BRIEF DESCRIPTION

In one embodiment, a probe device includes a measurement stage and an output connection. The measurement stage has a circuit configured to be connected with a power device under measurement, to measure one or more of a voltage or a current of the power device under measurement. The measurement stage is configured for at least one of a power supply rail or a reference of the measurement stage to be coupled to an electrode of the power device when the one or more of the voltage or the current is measured. The output connection is configured to communicate one or more of the voltage or the current of the power device under measurement that is measured or a derived parameter to a digital processing device or an external computer acquisition system.

In one embodiment, a gate driver includes a gate driver circuit and the probe device operably coupled to the gate driver circuit. The gate driver circuit is configured to drive a gate of the power device and to synchronously trigger measurement by the probe device.

In one embodiment, a measurement system includes a computer acquisition system and a probe device. The computer acquisition system includes one or more processors configured to monitor one or more of a voltage or a current of a power device. The probe device has a measurement circuit configured to be connected with the power device to measure the one or more of the voltage or the current of the power device wherein a reference of the measurement circuit is coupled to an electrode of the power device.

In one embodiment, a method connecting a probe device with a power device that is configured to control supply of electric current to one or more electronic devices by switching between activated and deactivated states. The probe device is connected with the power device such that a measurement circuit of the probe device is galvanically isolated from one or more of a ground reference of earth or a ground reference of a higher-level controller of the power device. The method also includes measuring one or more of a voltage or a current of the power device using the measurement circuit.

### BRIEF DESCRIPTION OF THE DRAWINGS

The subject matter described herein will be better understood from reading the following description of non-limiting embodiments, with reference to the attached drawings, wherein below:

FIG. 1 illustrates one embodiment of a measurement system;

FIG. 2 illustrates one of several probe devices shown in FIG. 1 according to one embodiment;

FIG. 3 is a circuit diagram of a measurement circuit for a differential probe device according to one example;

FIG. 4 is a circuit diagram of one embodiment of the probe device shown in FIGS. 1 and 2;

FIG. 5 illustrates control voltages applied to the power device (shown in FIG. 2) during activation of the power device according to another example;

FIG. 6 illustrates a flowchart of one embodiment of a method for using a high speed, galvanically isolated probe device to measure one or more characteristics of a power device.

FIG. 7 illustrates a gate driving assembly including the probe device integrated with a gate driver unit.

### DETAILED DESCRIPTION

One or more embodiments described herein provide systems, probe devices, and methods for monitoring power devices under operating conditions. The systems, probe devices, and methods may monitor power devices at sufficiently high bandwidth for being able to capture switching transients under operating conditions. The measurement bandwidth is typically larger than 1 MHz. The systems, probe devices, and methods can provide accurate measurements of voltages and currents present on a power device, such as an insulated gate bipolar transistor (IGBT) or other switching device. Many voltages and currents are monitored at the IGBT level with some requirements that cannot easily be met using standard measurement systems such as oscilloscopes. At least one embodiment described herein includes a galvanically isolated, high-bandwidth measurement system. In one implementation, a design with a digital processing unit is used to provide the measurements captured with high-throughput analog-to-digital converters (ADC) to an electrically insulated controller or acquisition system. The digital processing unit may apply some pre-processing to the digital samples. A digital memory may be used as a buffer to store the samples captured prior to being transferred to the controller or acquisition system. Alternatively, another implementation can be used, as described herein.

At least one embodiment of a high-speed isolated probe device described herein can be used for monitoring devices such as power switches (e.g., IGBTs, MOSFETs, RC-IGBTs, BIGTs, Thyristors, IGCTs, silicon carbide (SiC)-based devices, and the like) or power diodes and be based on a high-bandwidth analog stage of the probe device connected to a high-speed ADC of the probe device. The digital data is captured and processed into one or more integrated circuits (e.g., an FPGA) and then communicated to a computer/acquisition system (also referred to herein as a computer acquisition system). The probe device can include a very low capacitance isolation barrier between the power device under a test potential and the earth potential to ensure the correctness of the measurement in the presence of rapid changing high voltage common-mode voltage (e.g., on the order of several kilovolts per microsecond).

Due to the topology of power inverters and the high voltages in use with power inverters, an insulation barrier may be needed between a power device that controls the conduction of current (e.g., the IGBT) and the measurement equipment (e.g., the systems, probe devices, and methods described herein). As described herein, this isolation barrier is moved from the analog signal path present in some known systems to the digital communication interface of the probe devices described herein. While some known systems use an analog high voltage differential probe device connected to an oscilloscope or data acquisition system, this setup includes measurement errors induced by the common mode voltage and susceptibility of the measurement signal due to cabling to the oscilloscope. One or more embodiments described herein substantially minimizes or eliminates these problems by digitizing the measurement signals (e.g., voltages) directly at the test potential of the power device (e.g., an IGBT) and communicating the digitized measurement signals to the computer acquisition system using non electrically conductive paths, such as optical fibers. The active electronic components of the probe devices can be locally energized using a galvanic insulated power supply with low coupling capacitance.

One or more embodiments described herein provide for measuring systems and probe devices having very low stray capacitances of the measurement systems due to isolated power supply and optical communication channels of the probes. The systems and probe devices can have very low sensitivity to electromagnetic interference (EMI) due at least in part to the use of optical communication of the measurements of the power device. Alternatively, wireless communication, such as radio frequency (RF) communication, could be used to communicate the probe measurements.

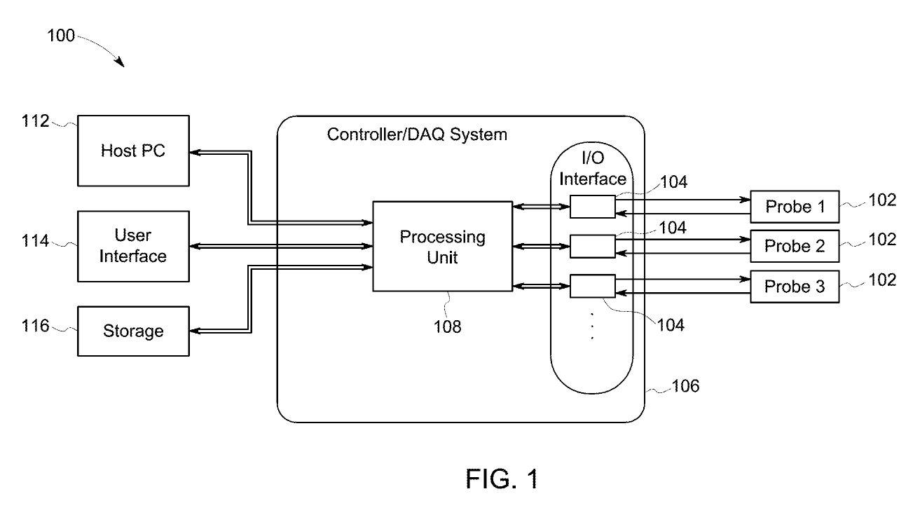

FIG. 1 illustrates one embodiment of a measurement system 100. The measurement system 100 measures one or more characteristics of a power device, such as control voltages of one or more power switches (e.g., IGBTs, MOSFETs, RC-IGBTs, BIGTs, Thyristors, IGCTs etc.) or power diodes. The measured characteristics can be used to calculate derived parameters of the power device, such as the gate charge of an IGBT, the rate of change in collector-emitter voltage Vce with respect to time (dVce/dt) at turn off of the power device, the collector-emitter voltage Vce overvoltage peak at turn off of the power device, and the like. The measurement system 100 includes several probe devices 102 that measure the voltages of one or more power devices. While the system 100 is shown as including three probe devices 102 (e.g., “Probe 1,” “Probe2,” and “Probe3” in FIG. 1), alternatively, the system 100 may have another number of probe devices 102, including a single probe device 102. The probe devices 102 are communicatively coupled with interfaces 104 of a computer acquisition system 106 in the system 100. The coupling between the probe devices 102 and the interfaces 104 may be non-conductive connections to provide galvanic isolation between the probe devices 102 and the interfaces 104). In one embodiment, the interfaces 104 are optical interfaces that optically communicate with the probe devices 102. For example, fiber optic cables may extend from the probe devices 102 to the interfaces 104 for use in communicating measured voltages.

The computer acquisition system 106 can include one or more processing units 108 that receive the measured voltages from the probe devices 102 via the interfaces 104. The processing units 108 can represent one or more processors, FPGAs, or the like. As described herein, the one or more processing units 108 can examine the voltages, currents, changes in the voltages and/or currents, or other characteristics of a power device under test in order to determine when to take remedial actions with respect to the power device. A computer device 112 (“Host PC” in FIG. 1) of the computer acquisition system 106 can represent one or more computers, laptops, servers, or the like. The computer device 112 may examine and/or store the measured voltages, currents, or the like, from the probe devices 102. In one embodiment, the computer device 112 may examine the voltages and/or changes in the voltages to determine when to take remedial actions. Optionally, the computer device 112 may implement one or more of the remedial actions described herein. In one aspect, the computer device 112 may include a feedback loop to a controller or to a gate driver. This feedback loop can be used to implement one or more remedial actions described below. A user interface 114 may be communicatively coupled with the processing unit 108 to generate output to a user. The user interface 114 can include a monitor, touchscreen, or other display or output device for communicating the measured voltages, currents, or the like. A storage 116 can represent one or more memories, such as cloud storage or a local memory, for storing information, such as measured voltages and/or currents.

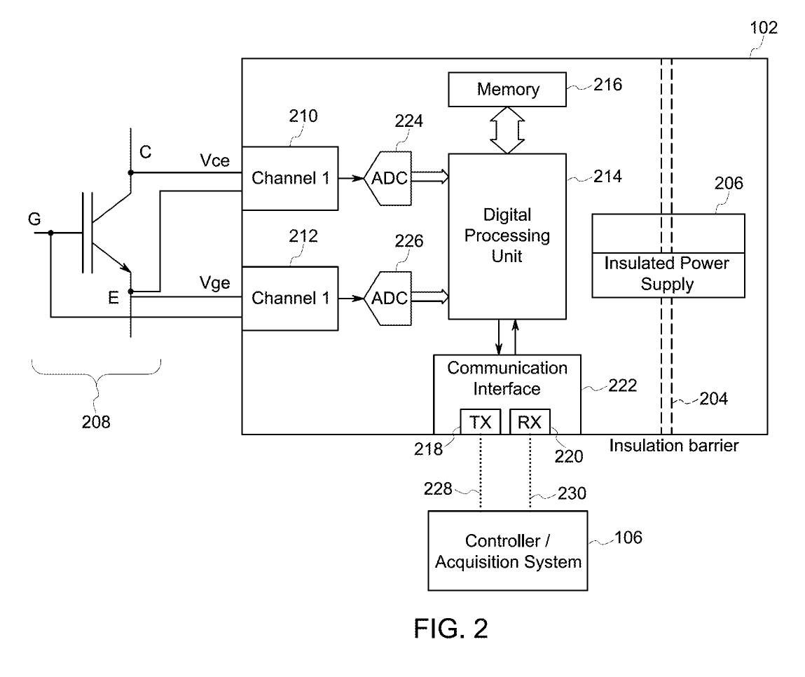

FIG. 2 illustrates one of the probe devices 102 shown in FIG. 1 according to one embodiment. The probe device 102 shown in FIG. 2 includes a power supply stage (or circuit), a measurement stage (or circuit), and an isolation stage (or circuit, as shown and described below). The power supply stage represents circuitry of the probe device 102 that receives electric power (e.g., current) from an external power supply and/or that includes a power supply. A power supply is a source of electric power, such as a battery or other source or provider of electric current. An external power source is separate from and outside of the probe device 102, while an internal power supply may be included in the probe device 102. The power supply stage includes a power supply 206 or a connection to a power supply 206, such as a battery or bulk power supply that is referenced to ground. The power supply stage can include one or more circuits (which also can be referred to as a “power supply circuit”) that conducts power (e.g., electric current, such as one ampere or another amount of current, and voltage, such as fifteen volts or another amount of voltage) to power a measurement stage of the probe device 102 (shown and described below).

The measurement stage of the probe device 102 includes one or more circuits (which also can be referred to as a “measurement circuit”) that measures one or more characteristics of a power device 208, such as a voltage or control voltage of the power device 208. The power device 208 can be a gate driver circuit in one embodiment, with a combination of the probe device 102 and the power device 208 referred to as a gate driver. The circuit of the measurement stage includes measurement probes 210, 212 that are conductively coupled with the power device 208. The measurement probes 210, 212 are coupled with the power device 208 to measure one or more characteristics of the power device 208. For example, the measurement probe 210 can be coupled with the power device 208 by one or more wires, cables, etc. to measure a voltage of the power device 208, such as a collector-emitter voltage. The measurement probe 212 can be coupled with the power device 208 by one or more wires, cables, etc. to measure another voltage of the power device 208, such as a gate-emitter voltage. The probes 210, 212 measure a differential mode voltage of the power device 208 by referencing the circuit of the measurement stage to one electrode of the power device 208. In one embodiment the measurement stage is referenced to the Emitter of and IGBT or Source of a MOSFET. Optionally, a different number of measurement connectors 210 can be included and/or different characteristics of the power device 208 can be measured.

The circuit of the measurement stage includes one or more digital processing units 214 that measure the voltage and/or current of the power device 208. The digital processing units 214 can represent one or more FPGAs or other circuits. The measured voltages and/or currents can be stored, or buffered, in a memory device 216, such as SDRAM or another memory, before being communicated to the computer acquisition system 106 (shown in FIG. 1) via an output connection 218 of a communication interface 222. Output connections 218, 220 can include fiber optic transmitters and receivers, respectively, for optically communicating with the computer acquisition system 106. Alternatively, the output connections 218, 220 can include wireless transmitters and receivers for wirelessly communicating with the computer acquisition system 106. The communication interface 222 provides an electrically insulated communication channel between the probe device 102 and the computer acquisition system 106. The communication interface 222 can communicate with the computer acquisition system 106 via one or more non-conductive communication channels 228, 230, such as via fiber optic channels, via wireless communication channels, or the like.

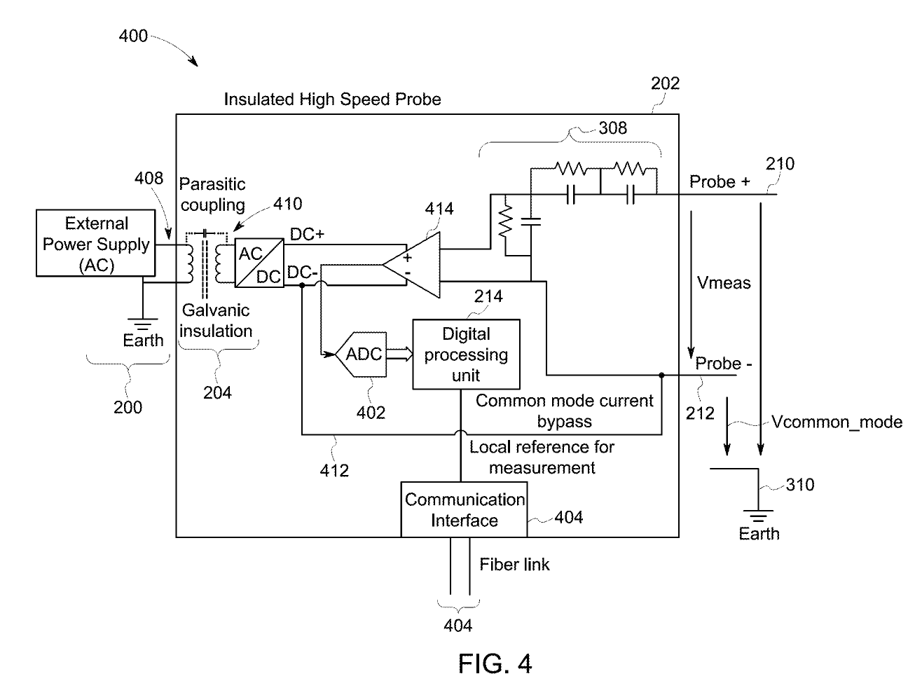

In one aspect, the digital processing circuit 214 can digitally measure the voltages and/or currents at a point of measurement. For example, voltages measured by the probes 210, 212 can be an analog signal that is directly provided to one or more analog-to-digital converters (ADC) 224, 226 that are included in the circuit of the measurement stage or the integrated circuit 214. The ADCs 224, 226 can be a high speed parallel ADC or another type of ADC. The voltages can be provided to the ADCs 224, 226 without referencing the voltages to ground before converting the analog voltages to digital signals. For example, in contrast to a differential probe device that measures the voltages of an IGBT, references the measured voltages to the ground or earth reference, then converts the measured voltages to a digital signal, the probe device 102 shown in FIG. 2 may digitize the measured voltages without previously referencing the measured voltages to a ground of earth (or earth potential), and/or without referencing the voltages to the ground reference of a higher level control system that is controlling operation of one or more devices using the power device. The probes 210, 212 can independently measure different voltages of the power device 208. For example, the probe 210 can measure the collector-emitter voltage (V_{CE}) and the probe 212 can measure the gate-emitter voltage (V_{GE}) of the power device 208. The reference for both these measured voltages is a reference of the measurement stage of the probe 102, which is connected with the emitter of the power device 208. In one embodiment, the reference for the measured voltages is connected to a power supply rail 412, as shown in FIG. 4.

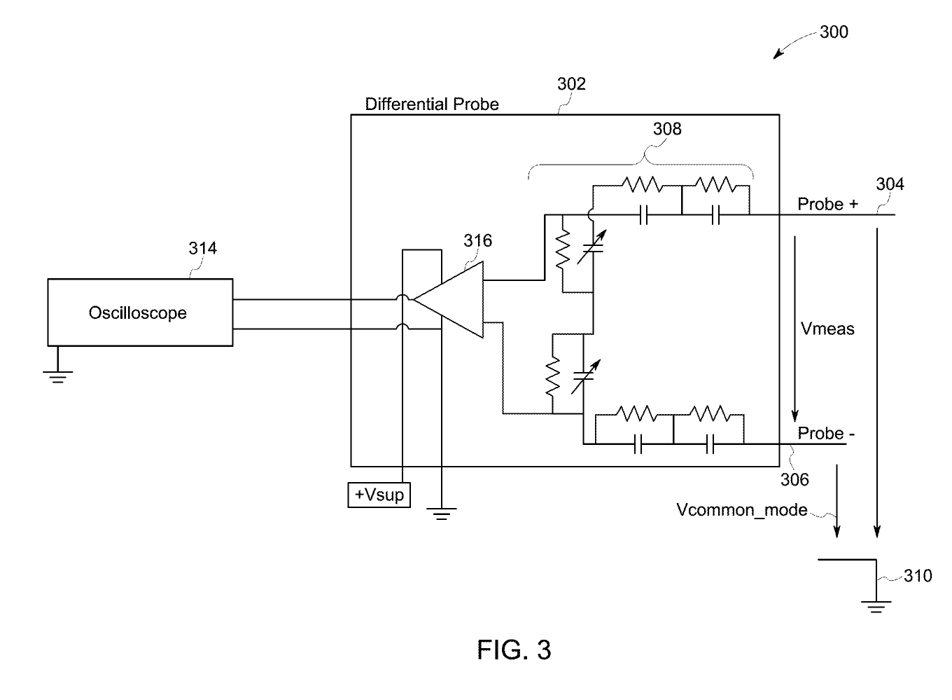

FIG. 3 is a circuit diagram of a measurement circuit 300 for a differential probe device 302 according to one example. The differential probe device 302 is different from the probe devices 102 shown in FIG. 2 and operates in a different manner, as described herein. The circuit 300 includes a differential probe that includes Probe+304 and Probe−306 in FIG. 3, which are coupled with an IGBT.

The differential probe includes a voltage divider chain 308 that divides and reduces the voltages measured by each of the probes 304, 306. The voltages measured by the differential probe are referenced to ground 310 and the difference between these referenced voltages represents the measured voltage (“Vmeas” in FIG. 3) of the IGBT. An operational amplifier 316 calculates a difference between the voltages measured by the probe+304 and the probe−306 as a ground-referenced voltage. This ground-referenced voltage is then transmitted to an oscilloscope 314 for digitization and presentation to an operator.

The differential probe device 302 suffers from several shortcomings. The common mode voltage for some power devices (such as IGBTs) may have relatively large changes (e.g., on the order of kilovolts per microsecond) while the differential voltage may have relatively small changes (e.g., on the order of volts per microsecond). Because the voltage that is measured for the power device 208 is measured as a difference between these voltages and the magnitude of the common mode voltage is considerably larger than the differential mode voltage (e.g., the voltage of interest), the static and dynamic responses of both voltage divider chains 308 may need to be very similar, if not identical, in order to accurately determine the measured voltage across the control terminals of the power device 208.

FIG. 4 is a circuit diagram of one embodiment of the probe device 102 shown in FIGS. 1 and 2. The circuit diagram in FIG. 4 illustrates a power supply circuit 408 that converts a direct current voltage provided from an external power supply into an alternating current voltage. This circuit 408 supplies electric energy to a measurement circuit 400 of the measurement stage in the probe device 102 via a transformer 410 of an isolation stage 204 of the probe device 102. The transformer 410 keeps the measurement circuit 400 galvanically isolated from the power supply circuit 408. Other options for a power supply of the probe device 102 include a step-down converter from a converter DC-link voltage, capacitive supply, or another source of electric energy.

The measurement circuit 400 illustrates the probe 210 (“Probe+” in FIG. 4) and the probe 210 connected with a voltage divider chain 308. The voltage between the output of the voltage divider 308 and the ground of the measurement stage (which is connected to probe 212 in FIG. 4) is the measured voltage Vmeas attenuated with the ratio of the voltage divider 308. In one embodiment, the output of the voltage divider is directly conducted to an ADC 402 where the voltage between the output of the voltage divider and the ground of the measurement stage is digitized without being previously referenced to ground 310. In another embodiment, an operational amplifier 414 is connected between the voltage divider 308 and the ADC 402. Additionally, a low impedance connection between the probe 212 and the ground of the measurement stage may be provided (“common mode current bypass” in FIG. 4). Because of the high input impedance of the operational amplifier, the common mode current sourced by the stray capacitance of the transformer 410 will be forced to flow in the low impedance bypass and does not disturb the measurement stage. In one embodiment, for measurement of voltages with low magnitude, the probe 210 is directly connected to the operational amplifier 414 or ADC 402 without any voltage divider. The ADC 402 converts the voltage signal into digital signals that are communicated to the integrated circuit 214 (“Processor” in FIG. 4). The digital processing unit 214 receives the differential voltage measured by the probes 210, 212 and communicates the measured voltage to the communication interface 222 for communication to the computer acquisition system 106 (shown in FIG. 1).

In contrast to a differential probe device (such as the differential probe device 302 shown in FIG. 3), the voltage measured by the probe 210 is referenced to the potential of the probe 212 which is also the power supply reference of the board electronics like the ADC 224, 226 and the digital processing unit 214, which allows for a single ended measurement (instead of a differential measurement). The power supply for the probe device 102 is isolated through the transformer 410, which has very low coupling capacitance.

In the differential probe device, the isolation is at the input (e.g., at the probes 304, 306) using the voltage divider chains 308 with the measured voltage being referenced to ground 310. The analog-to-digital conversion is performed inside the measurement circuit 400 at the relatively high moving potential of the common mode, instead of outside of the probe device 102 (e.g., such as in the oscilloscope 314 for the differential probe device 302).

The computer acquisition system 106 can examine the voltages and/or currents of the power device 208 that are measured by the probe 102. In one aspect, the computer acquisition system 106 can examine the voltages and/or changes in the voltages to determine deteriorating health of the power device 208. The voltages and/or changes in the voltages can represent degradation or impending failure of the power device 208.

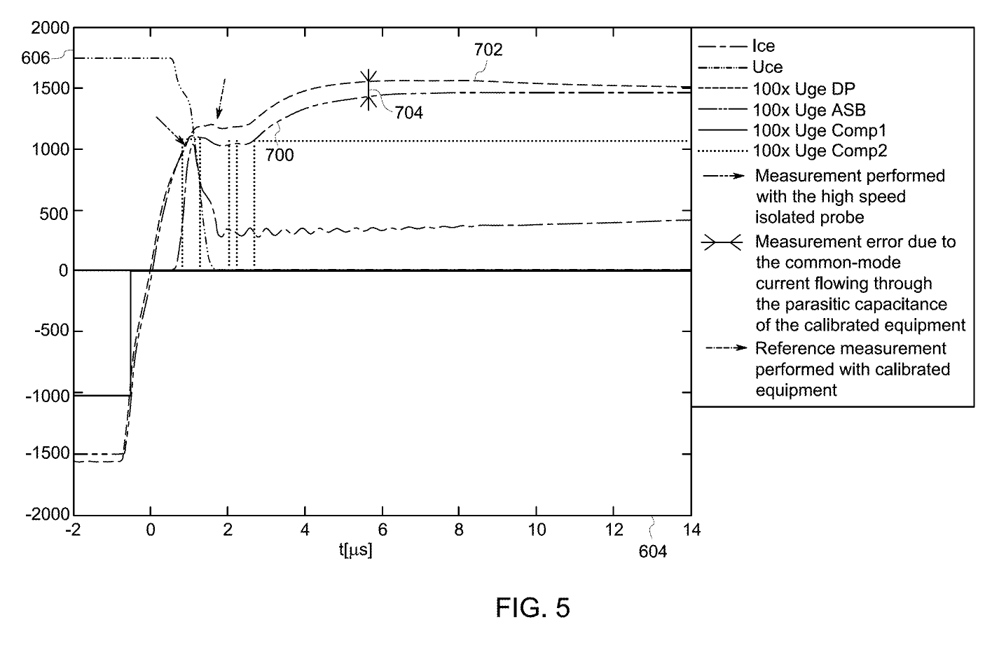

FIG. 5 illustrates control voltages 700, 702 applied to the power device 208 (shown in FIG. 2) during activation of the power device according to one example. The control voltage 700 represents the measured voltage of the power device 208 as measured by the probe device 102 shown and described herein. The control voltage 702 represents the measured voltage of the power device 208 as measured by a different probe device, such as the probe device 302 shown in FIG. 3. As shown in FIG. 5, the control voltage 700 measured by the probe device 102 includes less noise and measurement error relative to the control voltage 702 measured by the probe device 302. The measurement error in the control voltage 702 may be due to the fast change in the common mode voltage which is causing an error in the measured differential mode voltage if the capacitances of the two voltage dividers 308 are not perfectly matching in the differential probe device 302. Because the probe device 102 only includes one voltage divider 308, no matching is required and fast change in the common mode voltage change does not affect the measured signal. Additionally the voltage dividers in the differential probe device 302 can be designed to withstand the full common mode voltage which can be 1800V in the illustrated case of FIG. 5. The voltage divider in probe device 102 can be designed to withstand only the differential mode measurement voltage which is, in the illustrated case, two orders of magnitude smaller than the common mode voltage. This allows the design of a much more precise voltage divider (in attenuation and frequency response) and is especially beneficial for measurement of low magnitude differential mode voltages which are exposed to a large common mode voltage.

The voltages measured by the probe device 102 may be used to monitor the health or state of the power device 208. With respect to an IGBT as the power device 208, the probe device 102 may provide the measured control voltages to the computer acquisition system 106 (shown in FIG. 1). One or more of the computer 112, processing unit 110, and/or user interface 114 of the system 106 can compare the measured voltages to a designated threshold voltage to determine if the health of the power device 208 has deteriorated, which can indicate impending failure of the power device 208. For example, the system 106 may monitor the control voltage. If a characteristic of the control voltage like the threshold voltage Vth exceeds a threshold, then the increasing Vth can indicate deteriorating health and/or impending failure of the power device 208. Responsive to identifying a characteristic of the control voltage increasing above a threshold, the system 106 may implement one or more remedial actions. For example, the system 106 may generate an alarm to notify an operator via the user interface 114, may automatically deactivate the power device 208, or the like. As shown in FIG. 5, a measurement error 704 caused by the probe device 302 can result in too many false positive identifications of deteriorating health of the power device 208. The more accurate control voltages measured by the high speed galvanically isolated probe device 102 can reduce or eliminate these false positive identifications of deteriorating health of the power device 208.

In another example, different characteristics of the measured signals are compared with each other during a common (e.g., the same) operating condition of the power device 208. Based on relative changes in these characteristics, the health of the power device 208 can be determined. As another example, the temperature of the power device 208, the collector-emitter voltage Vice, and the collector-emitter current Ice can be measured in order to estimate thermal resistance of the power device 208, as described in U.S. Pat. No. 8,957,723 (the “'723 Patent”), the entire disclosure of which is incorporated by reference. Optionally, other characteristics of the power device 208 can be calculated based on the measured characteristics, such as the gate charge of the power device 208 (e.g., when the power device 208 is an IGBT), the rate of change in collector-emitter voltage Vce with respect to time (dVce/dt) at turn off of the power device 208, the collector-emitter voltage Vce overvoltage peak at turn off of the power device 208, and the like.

A change in one or more of these measured characteristics away from a standard or threshold value can be used as a basis for determining a health state of the power device 208, such as an indication of power device 208 damage that can be used to predict that the device 208 will fail in the near future (e.g., that the power switch is more likely than not to fail within a designated time threshold). In another aspect, a drift in a measured characteristic of the power device 208 away from the standard or threshold value (drift referring to a change over time, e.g., by more than a designated threshold) can be used similarly.

Another example of a characteristic that can be monitored is commutation inductance Lcom. Lcom is the stray inductance of the commutation path when a power semiconductor is switched. In case of busbar delamination, loosening of connections, or capacitor damage, Lcom increases. Lcom is reflected in the inductive voltage drop at turn-on and in the voltage overshoot at turn-off, across the power device 208. For the voltage overshoot at turn-off, also, the diode forward recovery may be considered. Vce and dIce/dt are measured at the gate drive and the commutation inductance is calculated according to the relation Lcom=deltaVce/dIce/dt.

In one embodiment, the probe device 102 can measure Vce and Ice, but may not have enough computing or processing capability for processing all data that the probe device 102 is acquiring or otherwise measuring in real time. The probe device 102 may store the sampled data for a time window into a digital memory (e.g., the storage 116) that is used as a buffer. The probe device 102 may then process the buffered data. The probe device 102 may need to determine the time instant at which a turn-off process starts to begin the data acquisition. The transition in the power device 208 make take less than 10 microseconds (or another time period), so the buffer size of the storage 116 can be dimensioned to store the data corresponding to 10 microseconds (or another time period). In such an example, a synchronization mechanism such as a digital trigger from the gate driver to the probe device 102 can be used to synchronize the processing of the data (e.g., to correspond or associated the buffered data with the time at which the data was measured).

In other example, the probe device 102 can obtain the synchronization mechanism from the gate driver on the driving characteristic being used by the gate driver for each switching event (e.g., turning on or turning off). The gate driver can drive the IGBT in different ways depending on the operating conditions (e.g., DC-link voltage, temperature, etc.). The Gate-Emitter voltage Vge of the IGBT may be different depending on the corresponding settings or operating conditions. The probe device 102 can examine the driving scheme used for the switching event to determine whether operation is abnormal or not.

In other example, the probe device 102 can obtain the synchronization mechanism from the gate driver on whether the deactivation is a normal turn-off or a soft-off. A soft-off is a special kind of turn-off or deactivation that is used to protect the IGBT from overcurrent or a short-circuit. The gate driver can determine the type of turn-off to use. The gate driver can communicate with the probe device to inform the probe device that the switching events should not be used for estimating normal IGBT parameters. The probe device may still record those events, but ay analyze the collected data in a different way.

In other example, the probe device 102 can obtain the synchronization mechanism from the gate driver on the DC-link voltage. This voltage can be continuously calculated by the gate driver, and also can be provided to the probe device for input in some estimation algorithms.

Other characteristics that can describe the health states of individual power devices 208 include forward voltage (Vf), threshold voltage (Vgeth), input capacity (Cge) and Miller capacity (Ccg), module inductance (Lmod), and thermal resistance between junction and case (Rthjc).

Lmod can be estimated by measuring between auxiliary and power emitter terminals of the power device 208, during a known current change, to obtain the voltage drop Vlmod across the module inductance. The inductance then can be determined according to Lmod=Vlmod/dIce/dt. Increasing Lmod may be indicative of debonding of the semiconductor device terminals of the power device 208. Optionally, other characteristics of the power device 208 may be monitored, as described in the '723 Patent.

In one embodiment the probe device 102 is integrated in the gate drive unit of the power switch. A gate drive unit typically provides a galvanically insulated power supply where the ground or one of the supply rails of the gate drive electronics is referenced to one of the control electrodes of the power switch, as well as an insulated communication link. Digital gate drivers also provide a digital processing unit. Integrating the probe device in the gate drive unit is therefore beneficial because of the shared infrastructure.

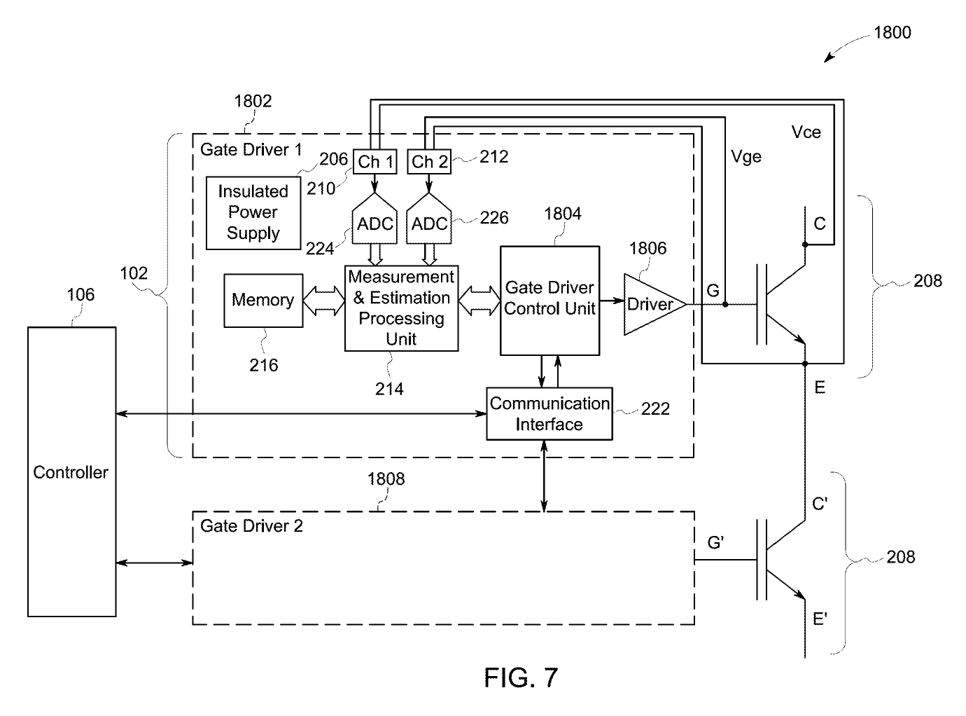

FIG. 7 illustrates a gate drive assembly 1800 according to one embodiment. The assembly 1800 includes the probe device 102 integrated with a gate drive unit 1802 (“Gate Driver 1” in FIG. 7). One difference between the probe device 102 shown in FIG. 2 and the probe device 102 shown in FIG. 7 is that the digital processing unit 214 (“Measurement & Estimation Processing Unit” in FIG. 7) is communicatively connected with a gate driver control unit 1804 of the gate drive unit 1802. The control unit 1804 controls operation of the gate drive unit 1802, and can represent one or more integrated circuits connected with a driver 1806. The control unit 1804 controls the voltage that is applied to the gate of the power device 208. The driver 1806 represents hardware circuitry that applies the voltage to the gate of the power device 208. A second gate drive unit 1808 (“Gate Driver 2” in FIG. 7) may be connected with the gate drive unit 1802, with another power device 208, and with the computer acquisition system 106 (“Controller” in FIG. 7) as shown in FIG. 7 to control operation of the power devices 208.

In one aspect, the measurement stage of the probe devices 102 described herein include a scope-like functionality where the measurement stage is triggered by an event, such as receipt of a command signal from the gate driver control unit 1804. Responsive to this triggering event, the voltage signals of the power device 208 can be captured in a time window at high resolution in a buffer for post-processing. This can allow information from the transients of the power device 208 to be extracted, the time instants when the power device 208 is switched on and off. Some known gate drivers do not have this capability and can only acquire “static” information, such as the collector-emitter voltage Vice in the off state and in the on state.

Communication between the gate driver control unit 1804 and the processing unit 214 of the probe device 102 is shown in FIG. 7 as a digital bus. This interface may receive a trigger (e.g., a synchronization mechanism) for the control unit 1804 to instruct the processing unit 214 when to start a new acquisition and may be used to communicate output from the processing unit 214 to the control unit 1804 to communicate the measured values.

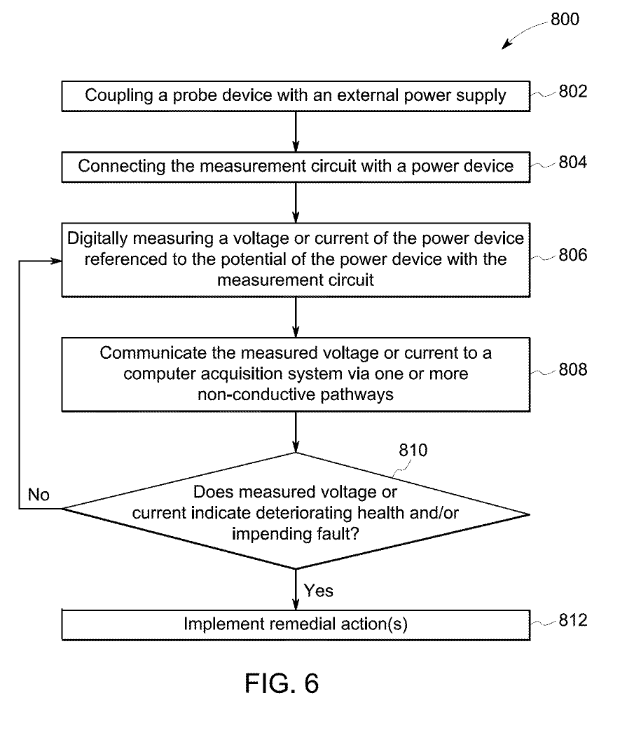

FIG. 6 illustrates a flowchart of one embodiment of a method 800 for using a galvanically isolated probe device to measure one or more characteristics of a power device. The method 800 may be used to manufacture and use the probe device 102 described herein (or another probe device). At 802, the probe device is coupled to an external power supply. At 804, the measurement circuit is connected with the power device. The measurement circuit measures one or more characteristics of the power device, such as a control voltage of an IGBT or other switching device. The measurement circuit and power supply circuit are galvanically isolated from each other. In other embodiments where the measurement circuit is supplied through a step-down converter from a converter DC-link voltage or capacitive supply the measurement circuit can be still be galvanically coupled to the power supply stage (e.g. through an inductor or capacitor). At 806, a characteristic of the power device is measured. For example, a control voltage of the power device can be digitally measured by the measurement circuit. At 808, the characteristic that is measured is communicated to a computer acquisition system. For example, the measured voltage can be optically communicated to the computer acquisition system. At 810, a determination is made as to whether the measured characteristic indicates deteriorating health and/or impending fault of the power device. For example, the measured voltage can be examined to determine if the voltage indicates deteriorating health and/or impending fault of the IGBT. If the measured characteristic does indicate deteriorating health and/or impending fault, then the method 800 can proceed toward 812. If the measured characteristic does not indicate deteriorating health and/or impending fault, then the method 800 can return toward 806 so that additional measurements of the characteristic can be made. The measured characteristics can be monitored over time (even if the characteristic does not exceed the threshold) in order to adapt model parameters of the power device to slow changes, such as aging of the device. Optionally, the measured characteristics can be monitored to observe operational conditions that are not dependent of the health of a power device. This can assist in eliminating the need for one or more additional sensors to monitor operational conditions. For example, the measured characteristics can be monitored to determine operating conditions of the power device (e.g., voltage, current, temperature, etc., including the dynamic information during the transients), to determine characteristics of the power device (e.g., gate capacitance, threshold voltage, module inductance, etc., which can be used to identify the kind of power device being driven), to determine characteristics of the power system (e.g., commutation inductance, thermal resistance between power device and ambient, etc.), to identify degradation of characteristics of the power device (e.g., increasing module inductance), and/or to identify degradation of characteristics of the power system (e.g., commutation inductance increasing, thermal resistance increasing, etc.).

At 812, one or more remedial actions are implemented. For example, responsive to the measured voltage indicating deteriorating health and/or impending fault of the power device, the computer acquisition system can shut down the power device, alert an operator via the user interface 112, or take some other action. Optionally, the measured characteristic or rise of the characteristic above a threshold can be logged into a statistics engine for monitoring for trends or other changes in operation of the power device, an alert or alarm signal may be communicated to a control system that controls operation of the power device, an alert or alarm signal may be communicated to the control system to direct the control system to alter a gate driving scheme (which is used to control the power device), etc.

In one embodiment, a probe device includes a measurement stage and an output connection. The measurement stage has a circuit configured to be connected with a power device under measurement, to measure one or more of a voltage or a current of the power device under measurement. The measurement stage is configured for at least one of a power supply rail or a reference of the measurement stage to be coupled to an electrode of the power device when the one or more of the voltage or the current is measured. The output connection is configured to communicate one or more of the voltage or the current of the power device under measurement that is measured or a derived parameter to a digital processing device or an external computer acquisition system.

In one aspect, the probe device also includes an isolation stage configured to be disposed between a power supply and the circuit of the measurement stage. The isolation stage is configured to galvanically isolate the circuit of the measurement stage from the power supply.

In one aspect, the measurement stage is galvanically coupled to a power supply stage that supplies electric power through one or more of an inductor or capacitor.

In one aspect, the output connection is configured to be non-conductively coupled with the external computer acquisition system.

In one aspect, the output connection includes optical connections configured to optically communicate the one or more of the voltage or the current that is measured to the external computer acquisition system.

In one aspect, the measurement stage includes one or more digital processing units configured to digitally measure the one or more of the voltage or the current of the power device under measurement at a point of measurement of the one or more of the voltage or the current.

In one aspect, the probe device is configured for the one or more of the voltage or the current that is measured to not be referenced to a ground reference or earth or a ground reference of a higher level controller of the power device before digitization.

In one aspect, the output connection is configured to wirelessly communicate the one or more of the voltage or the current that is measured to the external computer acquisition system.

In one aspect, the probe device also includes an isolation stage configured to be disposed between a power supply and the circuit of the measurement stage. The isolation stage is configured to galvanically isolate the circuit of the measurement stage from the power supply. The isolation stage includes a transformer configured to transfer power from the power supply to the circuit of the measurement stage without transferring electric current from the power supply to the circuit of the measurement stage.

In one aspect, the probe device is configured to be included in a gate driver that uses a synchronization mechanism to trigger measurement by the probe device.

In one embodiment, a gate driver includes a gate driver circuit and the probe device operably coupled to the gate driver circuit. The gate driver circuit is configured to drive a gate of the power device and to synchronously trigger measurement by the probe device.

In one embodiment, a measurement system includes a computer acquisition system and a probe device. The computer acquisition system includes one or more processors configured to monitor one or more of a voltage or a current of a power device. The probe device has a measurement circuit configured to be connected with the power device to measure the one or more of the voltage or the current of the power device wherein a reference of the measurement circuit is coupled to an electrode of the power device.

In one aspect, the probe device includes an isolation stage configured to be disposed between a power supply and the measurement circuit. The isolation stage is configured to supply power to the measurement circuit while galvanically isolating the measurement circuit from the power supply.

In one aspect, the probe device includes an output connection having optical connections configured to optically communicate the one or more of the voltage or the current that is measured to the external computer acquisition system.

In one aspect, the measurement circuit of the probe device includes one or more digital processing units configured to digitally measure the one or more of the voltage or the current of the power device at a point of measurement of the one or more of the voltage or the current.

In one embodiment, a method connecting a probe device with a power device that is configured to control supply of electric current to one or more electronic devices by switching between activated and deactivated states. The probe device is connected with the power device such that a measurement circuit of the probe device is galvanically isolated from one or more of a ground reference of earth or a ground reference of a higher-level controller of the power device. The method also includes measuring one or more of a voltage or a current of the power device using the measurement circuit.

In one aspect, the method also includes communicating the one or more of the voltage or the current of the power device that is measured to an external computer acquisition system via a non-conductive communication connection.

In one aspect, communicating the one or more of the voltage or the current includes optically communicating the one or more of the voltage or the current to the external computer acquisition system.

In one aspect, measurement of the one or more of the voltage or the current is synchronized to gate drive control signals.

In one aspect, measuring the one or more of the voltage or the current occurs during transients of the power device when the power device is switched on and off.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the inventive subject matter without departing from its scope. While the dimensions and types of materials described herein are intended to define the parameters of the inventive subject matter, they are by no means limiting and are exemplary embodiments. Many other embodiments will be apparent to one of ordinary skill in the art upon reviewing the above description. The scope of the inventive subject matter should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112(f), unless and until such claim limitations expressly use the phrase “means for” followed by a statement of function void of further structure.

This written description uses examples to disclose several embodiments of the inventive subject matter and also to enable a person of ordinary skill in the art to practice the embodiments of the inventive subject matter, including making and using any devices or systems and performing any incorporated methods. The patentable scope of the inventive subject matter is defined by the claims, and may include other examples that occur to those of ordinary skill in the art. Such other examples are intended to be within the scope of the claims if they have structural elements that do not differ from the literal language of the claims, or if they include equivalent structural elements with insubstantial differences from the literal languages of the claims.

The foregoing description of certain embodiments of the inventive subject matter will be better understood when read in conjunction with the appended drawings. To the extent that the figures illustrate diagrams of the functional blocks of various embodiments, the functional blocks are not necessarily indicative of the division between hardware circuitry. Thus, for example, one or more of the functional blocks (for example, processors or memories) may be implemented in a single piece of hardware (for example, a general purpose signal processor, microcontroller, random access memory, hard disk, and the like). Similarly, the programs may be stand-alone programs, may be incorporated as subroutines in an operating system, may be functions in an installed software package, and the like. The various embodiments are not limited to the arrangements and instrumentality shown in the drawings.

As used herein, an element or step recited in the singular and proceeded with the word “a” or “an” should be understood as not excluding plural of said elements or steps, unless such exclusion is explicitly stated. Furthermore, references to “one embodiment” of the inventive subject matter are not intended to be interpreted as excluding the existence of additional embodiments that also incorporate the recited features. Moreover, unless explicitly stated to the contrary, embodiments “comprising,” “including,” or “having” an element or a plurality of elements having a particular property may include additional such elements not having that property.

What is claimed is:

1. A probe device comprising:
a measurement stage having a circuit configured to be connected with a power device under measurement, to measure one or more of a voltage or a current of the power device under measurement, wherein the measurement stage is configured for at least one of a power supply rail or a reference of the measurement stage to be coupled to an electrode of the power device when the one or more of the voltage or the current is measured; and
an output connection configured to communicate one or more of the voltage or the current of the power device under measurement that is measured or a derived parameter to a digital processing device or an external computer acquisition system.

2. The probe device of claim 1, further comprising an isolation stage configured to be disposed between a power supply and the circuit of the measurement stage, the isolation stage configured to galvanically isolate the circuit of the measurement stage from the power supply.

3. The probe device of claim 1, wherein the measurement stage is galvanically coupled to a power supply stage that supplies electric power through one or more of an inductor or capacitor.

4. The probe device of claim 1, wherein the output connection is configured to be non-conductively coupled with the external computer acquisition system.

5. The probe device of claim 1, wherein the output connection includes optical connections configured to optically communicate the one or more of the voltage or the current that is measured to the external computer acquisition system.

6. The probe device of claim 1, wherein the measurement stage includes one or more digital processing units configured to digitally measure the one or more of the voltage or the current of the power device under measurement at a point of measurement of the one or more of the voltage or the current.

7. The probe device of claim 1, wherein the probe device is configured for the one or more of the voltage or the current that is measured to not be referenced to a ground reference or earth or a ground reference of a higher level controller of the power device before digitization.

8. The probe device of claim 1, wherein the output connection is configured to wirelessly communicate the one or more of the voltage or the current that is measured to the external computer acquisition system.

9. The probe device of claim 1, further comprising an isolation stage configured to be disposed between a power supply and the circuit of the measurement stage, the isolation stage configured to galvanically isolate the circuit of the measurement stage from the power supply, wherein the isolation stage includes a transformer configured to transfer power from the power supply to the circuit of the measurement stage without transferring electric current from the power supply to the circuit of the measurement stage.

10. The probe device of claim 1, wherein the probe device is configured to be included in a gate driver that uses a synchronization mechanism to trigger measurement by the probe device.

11. A gate driver comprising:
a gate driver circuit; and
the probe device of claim 1 operably coupled to the gate driver circuit, wherein the gate driver circuit is configured to drive a gate of the power device and to synchronously trigger measurement by the probe device.

12. A measurement system comprising:
a computer acquisition system comprising one or more processors configured to monitor one or more of a voltage or a current of a power device; and
a probe device having a measurement circuit configured to be connected with the power device to measure the one or more of the voltage or the current of the power device wherein a reference of the measurement circuit is coupled to an electrode of the power device.

13. The measurement system of claim 12, wherein the probe device includes an isolation stage configured to be disposed between a power supply and the measurement circuit, the isolation stage configured to supply power to the measurement circuit while galvanically isolating the measurement circuit from the power supply.

14. The measurement system of claim 12, wherein the probe device includes an output connection having optical connections configured to optically communicate the one or more of the voltage or the current that is measured to the external computer acquisition system.

15. The measurement system of claim 12, wherein the measurement circuit of the probe device includes one or more digital processing units configured to digitally measure the one or more of the voltage or the current of the power device at a point of measurement of the one or more of the voltage or the current.

16. A method comprising:
connecting a probe device with a power device that is configured to control supply of electric current to one or more electronic devices by switching between activated and deactivated states, the probe device connected with the power device such that a measurement circuit of the probe device is galvanically isolated from one or more of a ground reference of earth or a ground reference of a higher-level controller of the power device; and
measuring one or more of a voltage or a current of the power device using the measurement circuit.

17. The method of claim 16, further comprising communicating the one or more of the voltage or the current of the power device that is measured to an external computer acquisition system via a non-conductive communication connection.

18. The method of claim 17, wherein communicating the one or more of the voltage or the current includes optically communicating the one or more of the voltage or the current to the external computer acquisition system.

19. The method of claim 16, wherein measuring the one or more of the voltage or the current is synchronized to gate drive control signals.

20. The method of claim 19, wherein measuring the one or more of the voltage or the current occurs during transients of the power device when the power device is switched on and off.
